(19) United States
(12) Patent Application Publication
(10) Pub. No.: US 2025/0208227 A1
(43) Pub. Date: Jun. 26, 2025

(54) BATTERY DEGRADATION STATE ESTIMATION DEVICE, DEGRADATION SUPPRESSION SYSTEM, DEGRADATION STATE ESTIMATION METHOD, AND DEGRADATION SUPPRESSION METHOD

(71) Applicant: HONDA MOTOR CO., LTD., Tokyo (JP)

(72) Inventors: Takeshi FUJINO, Saitama (JP); Naoki SAKASHITA, Saitama (JP)

(21) Appl. No.: 18/851,698

(22) PCT Filed: Dec. 13, 2022
(86) PCT No.: PCT/JP2022/045816

§ 371 Date: Sep. 27, 2024

(30) Foreign Application Priority Data
Mar. 31, 2022 (JP) 2022-061375

(51) Int. Cl. G01R 31/392; G01R 31/367; G01R 31/389

(52) U.S. Cl. CPC G01R 31/392; G01R 31/367; G01R 31/389

(57) ABSTRACT

The purpose of the present invention is to provide a battery degradation state estimation method with which it is possible to highly accurately detect degradation due to reduction in battery capacity, and also provide a degradation suppression control method and a degradation suppression control system which are for suppressing degradation by using data of a result obtained by said battery degradation state estimation method. The present invention is configured to comprise: a degradation state estimation unit including a resistance value history acquisition unit that acquires a resistance value history of a battery in discharging for a predetermined time during traveling of a vehicle, and a degradation calculation unit that calculates the degradation state of the battery from the resistance value history of the battery; and a degradation suppression control unit for performing control on degradation suppression of the battery on the basis of the degradation state of the battery.

### TECHNICAL FIELD

The present invention pertains to a degradation state estimation device, degradation suppression system, degradation state estimation method, and degradation suppression method that are for a battery, and particularly pertains to a degradation state estimation device, degradation suppression system, degradation state estimation method, and degradation suppression method that are for a lithium metal secondary battery, which includes lithium metal in a negative electrode thereof.

### BACKGROUND ART

Patent Document 1 discloses that, for the object of monitoring the degradation state of each secondary battery in a case where secondary batteries are configured by being connected in series, a means for measuring a terminal voltage of each secondary battery is provided, and the degradation state of each secondary battery is determined based on change over time by each terminal voltage.

Patent Document 2 discloses a battery monitoring device for a secondary battery block configured from a plurality of secondary batteries that are connected in parallel, an internal resistance being calculated from an amount of voltage change and an amount of current change by the secondary battery block, and an abnormality in each secondary battery being determined based on an internal resistance value.
Patent Document 1: Japanese Unexamined Patent Application, Publication No. 2015-68783
Patent Document 2: Japanese Unexamined Patent Application, Publication No. 2006-138750

### DISCLOSURE OF THE INVENTION

### Problems to be Solved by the Invention

Degradation of an in-vehicle battery includes degradation where there is a decrease in capacity, and degradation where there is a decrease in output due to an increase in internal resistance. The determinations of degradation of a secondary battery in Patent Documents 1 and 2 are both based on measuring a decrease in output due to an increase in internal resistance, and are not based on detection of degradation due to a decrease in capacity.

A battery that includes lithium metal in a negative electrode thereof (a lithium metal battery LMB) has a small decrease in capacity over time, particularly at the initial state thereof, and accurately calculating the remaining capacity is difficult. As a result, there is decreased display accuracy for the range that an EV can travel.

The present invention is made in light of the above, and an object of the present invention is to provide a degradation state estimation device, degradation suppression system, degradation state estimation method, and degradation suppression method that are for a battery and enable degradation due to a decrease in the capacity of a battery to be set with high accuracy, targeting a battery that includes lithium metal in a negative electrode thereof (a lithium metal battery LMB).

### Means for Solving the Problems

In order to solve the problems described above, a battery degradation state (SOH) estimation device according to the present invention is a degradation state estimation device for estimating a capacity degradation state for a lithium metal secondary battery that includes lithium metal in a negative electrode, the degradation state estimation device being provided with: a resistance value history acquirer configured to acquire a history for a resistance value of the lithium metal secondary battery in discharging for a predetermined amount of time; and a degradation state calculator configured to, in a case where a state of charge SOC of the lithium metal secondary battery has entered a predetermined range, calculate a capacity degradation state SOH of the lithium metal secondary battery, based on the history for the resistance value acquired by the resistance value history acquirer. The resistance value history acquirer acquires a history for a first resistance value (Ra) that is of the lithium metal secondary battery in discharging for a first amount of time, and a history for a second resistance value (Rb) that is of the lithium metal secondary battery in discharging for a second amount of time that is longer than the first amount of time, and the degradation state calculator calculates the capacity degradation state SOH of the lithium metal secondary battery based on the history for the first resistance value (Ra) and the history for the second resistance value (Rb) that are acquired by the resistance value history acquirer.

As described in detail below, it is possible to know which stage of ranges a remaining battery capacity degradation state belongs to, from a resistance value (Ra) of the battery in discharging for a first amount of time when the state of charge (SOC) of the battery has entered a predetermined range and a resistance value (Rb) of the battery in discharging for a second amount of time different to the first amount of time when the state of charge (SOC) of the battery has entered the predetermined range.

In addition, in the battery degradation state (SOH) estimation device according to the present invention, it is effective for the resistance value history acquirer to acquire the history for the first resistance value and the history for the second resistance value while a vehicle is traveling. Discharging during travel by a vehicle is related to operation of the accelerator by the driver. It is possible to obtain the resistance value in various amounts of discharge time in accordance with normal driving, and it is possible to obtain the resistance of the battery in discharging for a predetermined amount of time in accordance with the driver consciously operating the accelerator for the predetermined amount of time.

In addition, in the battery degradation state (SOH) estimation device according to the present invention, it is effective to perform estimation when the state of charge (SOC) of the battery has entered a range of less than 30%. This is because the degradation state appears prominently when the state of charge (SOC) of the battery is low.

In addition, in the battery degradation state (SOH) estimation device according to the present invention, estimating the degradation state (SOH) of the battery at a time of charging is also included in addition to estimating the degradation state (SOH) of the battery at a time of discharging. Specifically, the degradation state is estimated by pausing a current when charging and acquiring a history of charging efficiency. Discharging and charging are performed for predetermined amount of time within the range of 1-10 seconds before and after the current is paused when charging, and the history of charging efficiency is obtained, as a result of which it is possible to estimate degradation at higher accuracy. There is good efficiency when the degradation state (SOH) of the battery at a time of charging is estimated when the state of charge (SOC) of the battery is in the range of 50% to 90%.

In addition, the battery degradation state (SOH) estimation device according to the present invention is also provided with a degradation state notifier configured to notify a user (the driver) of the degradation state SOH that is of the lithium metal secondary battery and is calculated by the degradation state calculator. A method for the notification may be, inter alia, displaying to a display device or a recommendation for attention in accordance with saving a fault code to a storage device when the degradation state worsens.

In addition, the battery degradation state (SOH) estimation device according to the present invention, together with a degradation suppression controller configured to execute degradation suppression control to suppress degradation of the lithium metal secondary battery, configures a battery degradation suppression system. The degradation suppression controller executes the degradation suppression control in a case where a value of second resistance value/first resistance value that is a ratio of the second resistance value with respect to the first resistance value has exceeded 3. A means for preventing degradation in the degradation suppression controller includes limiting charging or strengthening cooling.

A battery degradation state estimation method according to the present invention is a degradation state estimation method for estimating a degradation state for a lithium metal secondary battery that includes lithium metal in a negative electrode, the degradation state estimation method including: a resistance value history acquisition step of acquiring a history for a resistance value of the lithium metal secondary battery in discharging for a predetermined amount of time; and a degradation state calculation step of, in a case where a state of charge SOC of the lithium metal secondary battery has entered a predetermined range, calculating a capacity degradation state SOH of the lithium metal secondary battery, based on the history for the resistance value acquired in the resistance value history acquisition step.

A battery degradation suppression method according to the present invention includes: the resistance value history acquisition step and the degradation state calculation step in the degradation state estimation method; and a degradation suppression control step of, based on the degradation state SOH calculated in the degradation state calculation step, executing degradation suppression control to suppress degradation of the lithium metal secondary battery.

### Effects of the Invention

In this manner, the present invention has the effects of enabling the degradation state (SOH) of a battery to be accurately determined from the resistance value (Ra) of the battery in discharging for a first amount of time when the state of charge (SOC) of the battery has entered a predetermined range and the resistance value (Rb) of the battery in discharging for a second amount of time different to the first amount of time when the state of charge (SOC) of the battery has entered the predetermined range, and performing degradation prevention control based on an accurate result of determining the degradation state (SOH) of the battery, whereby it is possible to gently guide degradation of the battery.

### BRIEF DESCRIPTION OF THE DRAWINGS

FIG. 1 is a block diagram for a degradation control system according to the present invention;

FIG. 2 is a view that illustrates a capacity degradation characteristic for a lithium-ion battery LIB;

FIG. 3 is a view that illustrates a capacity degradation characteristic for a lithium metal battery LMB;

FIG. 4 is a view that expresses a history for a resistance Ra and a resistance Rb of a battery according to the present invention; and

FIG. 5 is a view that illustrates a flow for degradation suppression control according to the present invention.

### PREFERRED MODE FOR CARRYING OUT THE INVENTION

The present invention is premised upon a lithium metal secondary battery being used as a battery. The lithium metal secondary battery is characterized by being provided with a positive electrode, a negative electrode, and a separator and an electrolytic solution that are disposed between the positive electrode and the negative electrode, and has a lithium metal layer as the negative electrode. The lithium metal layer is formed by causing lithium metal particles to precipitate on a lithium foil or a negative electrode current collector. Lithium metal secondary batteries have an energy density that is very high in comparison to lithium-ion secondary batteries that are common heretofore, and it is expected that lithium metal secondary batteries will be put to practical use.

The positive electrode is formed by a layer that includes a positive electrode active material, a binder, and an electrically conductive aid. The positive electrode active material may be lithium cobalt oxide (LiCoO₂), lithium nickelate (LiNiO₂), LiNiₚMn_{q}CoᵣO2 (p+q+r=1), LiNiₚAl_{q}CoᵣO₂ (p+q+r=1), lithium manganate (LiMn₂O₄), hetero-element-substituted Li—Mn spinel expressed by Li₁₊ₓMn_{2-x-y}M_{y}O₄ (x+y=2, M=at least one element selected from Al, Mg, Co, Fe, Ni, and Zn), lithium titanate (an oxide that includes Li and Ti), lithium metal phosphate (LiMPO₄, M=at least one element selected from Fe, Mn, Co, Ni), or the like. It is preferable for LiNi_{0.8}Co_{0.1}Mn_{0.1}O₂ (NCM811) to be used as the positive electrode active material.

The electrolytic solution includes an organic solvent and an electrolyte. Regarding the organic solvent, as a first organic solvent, for example, it is possible to use 1,1,2,2-tetrafluoro-1-(2,2,2-trifluoroethoxy) ethane or a hydrofluoroether such as methyl nonafluoroisobutyl ether and methyl nonafluorobutyl ether, which are chain hydrocarbons that are the result of fluorine substitution. In addition, as a second organic solvent, for example, it is possible to use 1,2-dimethoxyethane (DME), ethylene carbonate (EC), propylene carbonate (PC), sulfolane (SL), dimethyl carbonate (DMC), diethyl carbonate (DEC), ethyl methyl carbonate (EMC), or the like. It is possible to use both of the first organic solvent and the second organic solvent. The electrolyte is a supply source for lithium ions that are a charge transfer medium, and includes a lithium salt. As the lithium salt, it is possible to use at least one selected from the group consisting of LiFSI, LiPF₆, LiBF₄, LiClO₄, LiASF₆, LiCF₃SO₃, LiC(CF₃SO₂)₃, LiN(CF₃SO₂)₂(LiTFSI), LiN(FSO₂)₂(LiFSI), and LiBC₄O₈. From these, LiFSI is preferably used as the electrolyte.

Description is given below regarding embodiments of the present invention with reference to the drawings.

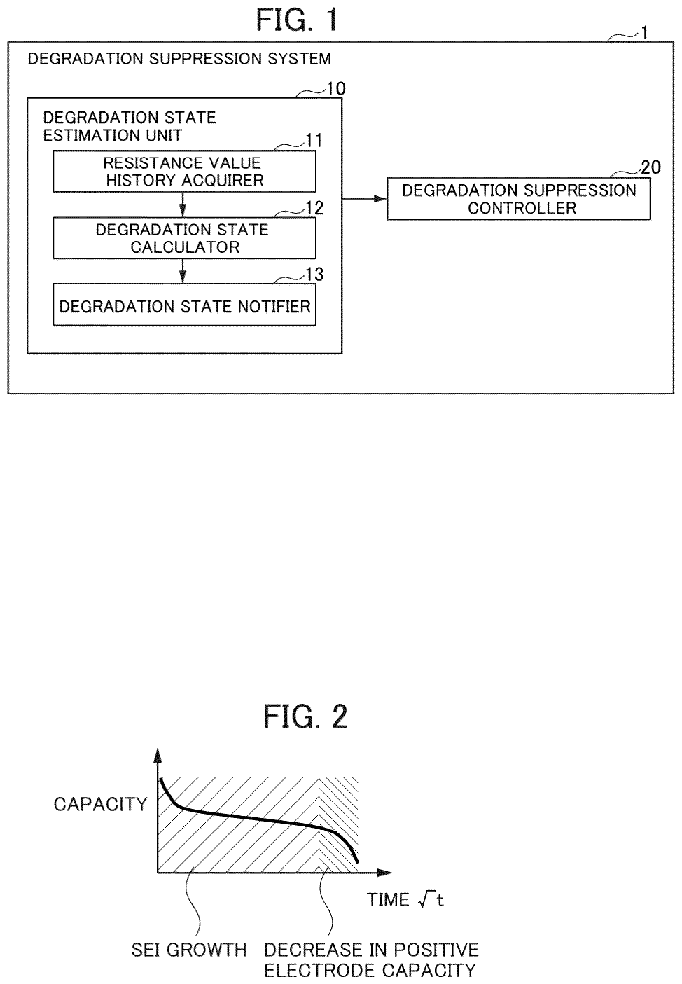

FIG. 1 is a block diagram for a degradation control system according to the present invention. A degradation control system 1 according to the present invention includes: a degradation state estimation unit 10 that is provided with a resistance value history acquirer 11, a degradation state calculator 12, and a degradation state notifier 13; and a degradation suppression controller 20.

The resistance value history acquirer 11 in the degradation state estimation unit 10 sequentially obtains an internal resistance value of a battery at a time of charging or discharging, while a vehicle is traveling. How the internal resistance value is obtained is described below. From an obtained resistance value and a closed-circuit voltage of the battery, it is possible to estimate an open-circuit voltage and estimate a state of charge (SOC) of the battery.

When an estimated state of charge (SOC) of the battery has become less than 30%, an internal resistance value R is obtained during each of two instances of discharging that have different amounts of discharge time. Typically, when there are different amounts of discharge time, internal resistance values during said discharging also differ, and the resistance value increases the longer the amount of discharge time. For example, let a resistance value for when the amount of discharge time is 1 second be Ra, and a resistance value for when the amount of discharge time is 30 seconds, for example, be Rb. When respective resistance values Ra0 and Rb0 for the initial state of the battery are known, a rate of increase is obtained for each of the current resistance values Ra and Rb of the battery, with respect to the initial state.

Historical data for resistance values R (Ra, Rb) acquired by the resistance value history acquirer 11 is sent to the degradation state calculator 12. The degradation state calculator 12 holds data that is for an amount of time in which the battery is operating and indicates a relationship between a remaining battery capacity degradation state (SOH) classification, a rate of increase in Ra that is a resistance value for when an amount of discharge time is 1 second, and a rate of increase in Rb that is a resistance value for when an amount of discharge time is 30 seconds. The degradation state calculator 12 can make a comparison with resistance value R (Ra, Rb) historical data sent from the resistance value history acquirer 11 to thereby determine which classification, divided by degradation state (SOH), the current remaining battery capacity degradation state (SOH) belongs to. Data regarding a result obtained by the degradation state calculator 12 is sent to the degradation state notifier 13, an effective remaining capacity is calculated from the SOC at that time, and a travelable distance or a battery capacity degradation rate is calculated and notified to a user (the driver).

In addition, the data regarding the result obtained by the degradation state calculator 12 is sent to the degradation suppression controller 20, and degradation suppression control that corresponds to the degradation state (SOH) classification to which the battery belongs to at present and the ratio of Rb to Ra (the value of Rb/Ra) is performed.

A reason why capacity degradation of a lithium metal battery LMB differs to degradation of a lithium-ion battery LIB is described by way of a comparison. Note that, as described above, graphite or the like is used as a negative electrode member in a conventional lithium-ion battery LIB, whereas lithium is used as a negative electrode member in a lithium metal battery LMB.

FIG. 2 is a view that illustrates a capacity degradation characteristic for a lithium-ion battery LIB. In the lithium-ion battery LIB, a SEI is generated at an electrode due to use of the battery, but, at an initial stage of battery use, decreasing active lithium within the battery due to the generation of a SEI is a main cause of the degradation of the remaining capacity of the battery. Accordingly, even during an initial stage of battery use, degradation proceeds at a specific rate, as it is comparatively easy to detect the degradation state of the remaining capacity. Note that, when a state is entered in which a decrease in the capacity of a positive electrode overtakes SEI growth, the degradation greatly proceeds.

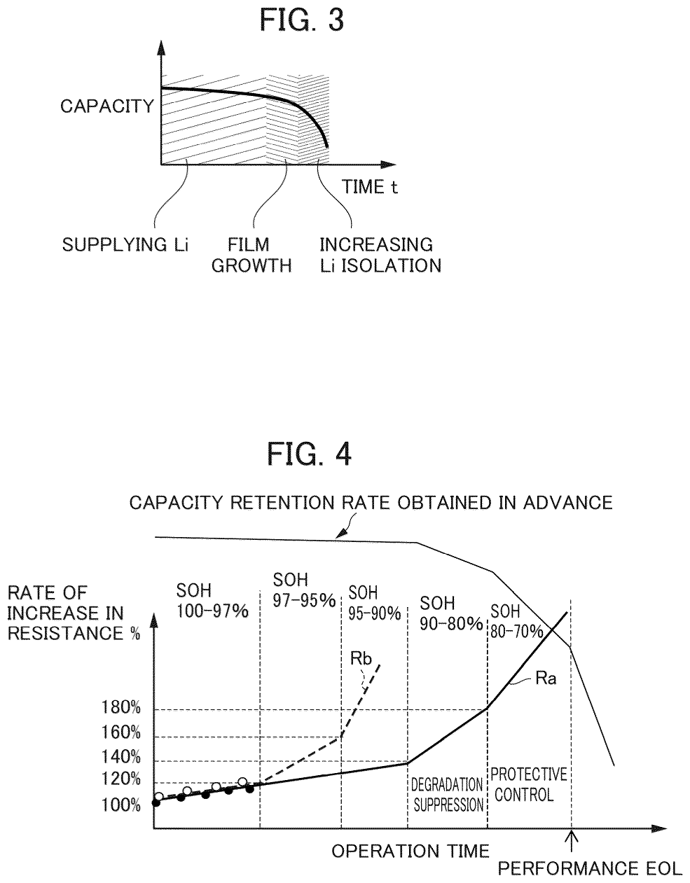

FIG. 3 is a view that illustrates a capacity degradation characteristic for degradation of a lithium metal battery LMB. Even in the lithium metal battery LMB, a coating is generated at an electrode due to usage of the battery, but, at an initial stage of battery use, a decrease of active lithium within the electrode due to the coating being generated is compensated by excess lithium in the negative electrode and, in the initial stage of battery use, there is little change in capacity, and a capacity degradation state is less likely to be detected. The margin of decrease for the remaining capacity is smaller than for the lithium-ion battery LIB. However, afterwards, precipitated metallic lithium further loses electrical conductivity and enters an isolated state, the capacity of the battery suddenly decreases, and a service life EOL is reached.

In this manner, the lithium metal battery LMB can be said to have a property of, through a time period that elapses during use of the battery, there is a small level of degradation of the remaining capacity until a certain time period and, although it is difficult to detect how far degradation has progressed by a differential capacity, degradation proceeds when a certain time period is exceeded, and the service life EOL is reached. Accordingly, for a lithium metal battery LMB, there can be said to be greater demand to monitor the degradation status from an initial state in which the level of degradation of the remaining capacity is low, in comparison to a conventional lithium-ion battery LIB. In this context, the battery degradation state estimation method according to the present invention has a high accuracy for the estimation of the degradation state of a battery, and can be said to be strongly required in the monitoring of degradation of a lithium metal battery LMB.

Next, the battery degradation state estimation method according to the present invention is described in detail using FIG. 4.

While a vehicle is traveling, due to, inter alia, the driver operating the accelerator or brake, discharge states and charging states that have various temporal lengths arise in a battery that is mounted in the vehicle. A system in the vehicle automatically detects a characteristic (an I-V characteristic) for the relationship between a closed-circuit voltage and a current value, in association with the amount of time (the length) of discharging or charging, and stores the relationship in a storage device. The resistance value R is sequentially calculated from I-V characteristics for discharging and charging during travel.

It is possible to obtain an open-circuit voltage OCV of a battery from the resistance value R and a closed-circuit voltage CCV of the battery, which are obtained as described above, and finally estimate a state of charge (SOC) of the battery from an OCV-SOC relationship. When the state of charge (SOC) of the battery has become less than 30%, two resistance values are obtained during instances of discharging that have different lengths of time for discharging. It is possible to cause the lengths of time for discharging to differ by having different amounts of output time during travel, specifically by having different lengths during which the accelerator is pressed.

For example, the resistance value Ra for when the length of time for discharging is 1 second and the resistance value Rb for when the length of time for discharging is 30 seconds are obtained from an I-V characteristic that is for during discharging. Assuming that the values of the resistance value Ra0, which is for when the length of time for discharging is 1 second, and the resistance value Rb0, which is for when the length of time for discharging is 30 seconds, are for an initial stage of using the battery and are acquired in advance, it is possible to obtain rates of increase that are in the current resistance values Ra and Rb of the battery, and are with respect to the battery resistance values Ra0 and Rb0 at the initial stage of using the battery.

Meanwhile, data regarding the relationship between an amount of time a battery is used (an amount of driving time), the rates of increase in the resistance values Ra and Rb, and the remaining battery capacity degradation SOH is held in the system in the vehicle. FIG. 4 is a graph that illustrates the relationship between the amount of time a battery is used (amount of driving time), the rates of increase in the resistance values Ra and Rb, and remaining battery capacity degradation SOH. According to this graph, there is a specific relationship between the amount of time that the battery is operating and the resistance values Ra and Rb, and it is possible to know a range for the remaining battery capacity degradation state SOH in accordance with respective ranges for the resistance values Ra and Rb.

For example, if the rates of increase in the resistance values Ra and Rb are in the range 100-120%, the remaining battery capacity degradation state SOH is known to be in the range of 100-97. In addition, if the rate of increase in the resistance value Rb is in the range 120-160%, the remaining battery capacity degradation state SOH is known to be in the range of 97-95. Similarly, if the rate of increase in the resistance value Ra is in the range of less than or equal to 140% and the rate of increase in the resistance value Rb is in the range of greater than or equal to 160%, the remaining battery capacity degradation state SOH is known to be in the range of 95-90. Similarly, if the rate of increase in the resistance value Ra is in the range of 140-180%, the remaining battery capacity degradation state SOH is known to be in the range of 90-80. Finally, if the rate of increase in the resistance value Ra is in the range of greater than or equal to 180%, the remaining battery capacity degradation state SOH is known to be in the range of 80-70.

The system in the vehicle compares the resistance value Ra that is for when the length of time for discharging is 1 second and the resistance value Rb that is for when the length of time for discharging is 30 seconds, which are obtained as described above, with data that is stored in advance in the vehicle system and is regarding the relationship indicated in FIG. 4 between the rates of increase in the resistance values Ra and Rb and the remaining battery capacity degradation SOH, as a result of which it is possible to determine in which range the current remaining battery capacity degradation state SOH falls under.

Determination result data regarding the range for the acquired current remaining battery capacity degradation state SOH is, for example, displayed on a display device, whereby the determination result data can be known by a user. Note that the remaining battery capacity degradation state SOH does not necessarily need to be always known by a user such as the driver. Therefore, instead of being displayed on a display device, the remaining battery capacity degradation state SOH may, for example, be notified to a user by an alert indication on an alarm apparatus when the need to notify the degradation state to a user has arisen.

In addition, the system in the vehicle performs deterioration suppression control based on the range for the current remaining battery capacity degradation state SOH, and the value of the ratio (Rb/Ra) for the resistance value Ra and the resistance value Rb. A method such as limiting charging or strengthening cooling may be given as a method for deterioration suppression. In particular, when the ratio (Rb/Ra) for the resistance value Ra and the resistance value Rb exceeds 3, it is assumed that the remaining battery capacity has approached the service life EOL, and protective control such as rapid cooling of the battery is performed.

Note that, in the above description, the remaining battery capacity degradation state SOH is estimated by obtaining the resistance values Ra and Rb during discharging, but it is also possible to estimate the remaining battery capacity degradation state SOH during charging. In this case, a history of charging efficiency is acquired after pausing current when charging. Discharging and charging are performed for a predetermined amount of time within the range of 1-10 seconds before and after the current is paused when charging, whereby it is possible to acquire the history of charging efficiency with greater efficiency. Note that, in the estimation of the remaining battery capacity degradation state SOH when charging, it is more efficient to pause the current when charging when the state of charge (SOC) of the battery is in the range of 50-90%.

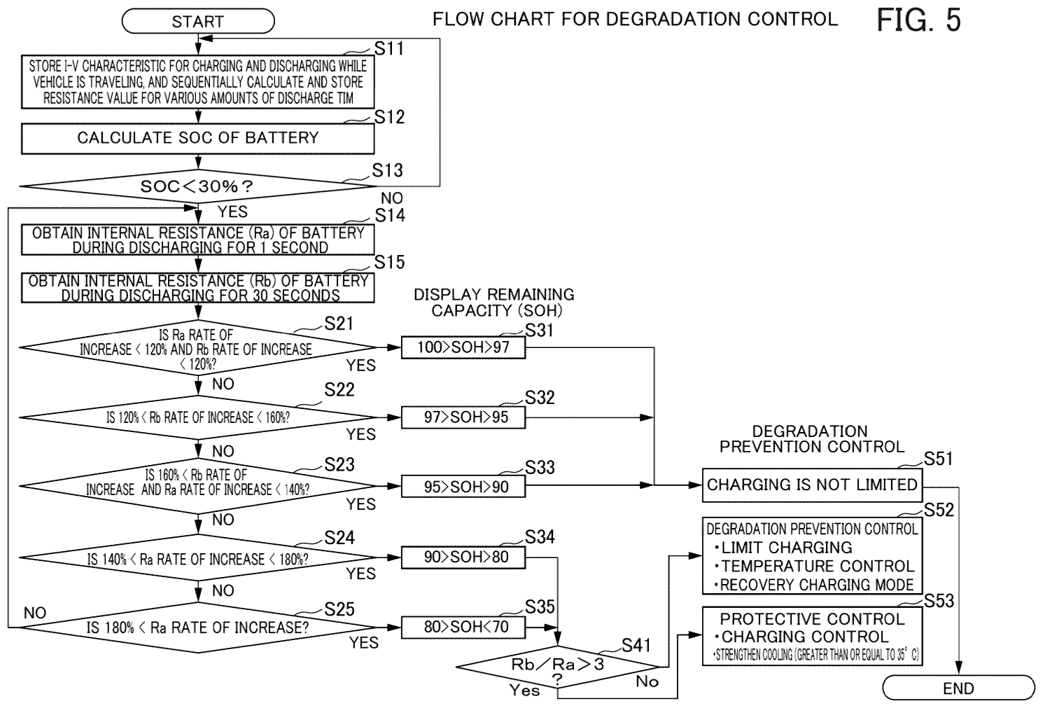

Next, using the flow chart in FIG. 5, description is given regarding degradation suppression control according to the present invention. The flow in FIG. 5 starts by firstly storing an I-V characteristic for charging and discharging during travel by a vehicle, and sequentially calculating and storing a resistance value for various amounts of discharge time (step S11), and using the method described above to obtain the state of charge SOC of the battery (step S12).

Next, it is determined whether the state of charge of the battery is less than 30% (step S13). If the answer is NO, in other words if it is determined that the state of charge is greater than or equal to 30%, step S11 is returned to, and the loop of step S11, step S12, step S13, step S11, . . . is repeated until YES is answered in step S13.

When YES is answered in step S13, in other words when the state of charge of the battery is less than 30%, next step S14 and step S15 are advanced to, and the internal resistance (Ra) of the battery during discharging for 1 second is acquired (step S14), and the internal resistance (Rb) of the battery during discharging for 30 seconds is acquired (step S15). It is known that the degradation state of a battery appears more prominently the lower the state of charge of the battery, and the state of charge of the battery being less than 30% is waited for in order to precisely detect the degradation state with good accuracy.

Values that are for the internal resistance (Ra) of the battery during discharging for 1 second and the internal resistance (Rb) of the battery during discharging for 30 seconds and are for an initial stage of using the battery are known in advance. Therefore, it is possible to obtain rates of increase, with respect to the initial state, in the current internal resistance (Ra) of the battery during discharging for 1 second and internal resistance (Rb) of the battery during discharging for 30 seconds that were obtained in step S14 and step S15.

If, in accordance with the obtained rate of increase in each of the internal resistance (Ra) of the battery during discharging for 1 second and the internal resistance (Rb) of the battery during discharging for 30 seconds that are of the battery at present, the range in which the Ra rate of increase is <120% and the Rb rate of increase is <120% is applicable (step S21), then the remaining battery capacity degradation state (SOH) satisfies 97<SOH<100 and a display indicating this is made on a display device (step S31). In this case, it is assumed that the degradation state has not advanced, and a measure such as limiting charging is not taken (step S51).

Similarly, if within the range where 120%<the Rb rate of increase <160% (step S22), a display indicating that 95<SOH<97 is made on the display device (step S32), and a measure such as limiting charging is also not taken in this case (step S51). Similarly, if within the range where the Ra rate of increase <120% and 160%<the Rb rate of increase (step S23), a display indicating that 90<SOH<95 is made on the display device (step S33), and a measure such as limiting charging is also not taken in this case (step S51).

In addition, if within the range where 140%<the Ra rate of increase <180% (step S24), a display indicating that 80<SOH<90 is made on the display device (step S34). Here, it is determined whether the value of Rb/Ra exceeds 3 (step S41). In a case where the answer is NO, in other words in the case where the value of Rb/Ra does not exceed 3, degradation prevention control is performed (step S52). In contrast, in a case where the answer is YES, in other words in the case where the value of Rb/Ra exceeds 3, protective control is performed (step S53). Note that it can be said that there is a low possibility that the value of Rb/Ra will exceed 3 in the case where 80<SOH<90 and, in many cases in this range, there is a transition to step S52 in which degradation prevention control is performed for the most part.

Finally, if within the range 180%<the Ra rate of increase (step S25), a display indicating that 70<SOH<80 is made on the display device (step S35). In this case as well, it is next determined whether the value of Rb/Ra exceeds 3 (step S41). In a case where the answer is NO, in other words in the case where the value of Rb/Ra does not exceed 3, degradation prevention control is performed (step S52). In contrast, in a case where the answer is YES, in other words in the case where the value of Rb/Ra exceeds 3, protective control is performed (step S53). Note that it can be said that there is a high possibility that the value of Rb/Ra will exceed 3 in the case where 70<SOH<80, and there is a high possibility that protective control will be necessary in this range.

In the degradation prevention control (step S52), a method for comparatively gradual degradation prevention is employed. Specifically, a measure such as limiting charging, temperature control, or a recovery charging mode is taken. The recovery charging mode is a measure in which discharging is temporarily interrupted, and charging at a low rate is performed. In contrast to this, in protective control (step S53), a strong, forcible method for preventing degradation is employed. Specifically, the temperature at which to start cooling is changed, for example, rapid cooling is performed at a temperature of 35° C. or more. In relation to charging, a strong limitation is also imposed on a permissible current value. By virtue of the degradation prevention control (step S52) and the protective control (step S53), it is possible to slow the rate at which battery degradation advances.

An embodiment is used above to give a description regarding an aspect for working the present invention, but the present invention is not in any way limited to the embodiment described above, and it goes without saying that the present invention includes matter that can be worked in various aspects, within a range that does not deviate from the spirit of the present invention.

### EXPLANATION OF REFERENCE NUMERALS

1 Degradation suppression system
10 Degradation state estimation unit
11 Resistance value history acquirer
12 Degradation state calculator
13 Degradation state notifier
20 Degradation suppression controller

1. A degradation state estimation device for estimating a degradation state of a lithium metal secondary battery that includes lithium metal in a negative electrode, the degradation state estimation device comprising:
a resistance value history acquirer configured to acquire a history for a resistance value of the lithium metal secondary battery in discharging for a predetermined amount of time; and
a degradation state calculator configured to, in a case where a state of charge SOC of the lithium metal secondary battery has entered a predetermined range, calculate a degradation state SOH of the lithium metal secondary battery, based on the history for the resistance value acquired by the resistance value history acquirer.

2. The degradation state estimation device according to claim 1, wherein
the resistance value history acquirer acquires a history for a first resistance value that is of the lithium metal secondary battery in discharging for a first amount of time, and a history for a second resistance value that is of the lithium metal secondary battery in discharging for a second amount of time that is longer than the first amount of time, and
the degradation state calculator calculates the degradation state SOH of the lithium metal secondary battery based on the history for the first resistance value and the history for the second resistance value that are acquired by the resistance value history acquirer.

3. The degradation state estimation device according to claim 2, wherein
the resistance value history acquirer acquires the history for the first resistance value and the history for the second resistance value while a vehicle is traveling, and
the degradation state calculator calculates the degradation state SOH in a case where the state of charge SOC of the lithium metal secondary battery has become less than or equal to 30%.

4. The degradation state estimation device according to claim 2, wherein the first amount of time is 1 second, and the second amount of time is 5 seconds to 30 seconds.

5. The degradation state estimation device according to claim 1, further comprising:
a charge/discharge controller configured to, in a case where the state of charge SOC of the lithium metal secondary battery is within the range of 50% to 90%, execute charge/discharge control to pause a current during charging of the lithium metal secondary battery, discharge the lithium metal secondary battery for a predetermined amount of time, and resume charging of the lithium metal secondary battery,
wherein the resistance value history acquirer acquires the history for the resistance value while charging the lithium metal secondary battery, and
the degradation state calculator calculates the degradation state SOH based on the history for the resistance value that is acquired by the resistance value history acquirer while the lithium metal secondary battery is charging.

6. The degradation state estimation device according to claim 1, further comprising: a degradation state notifier configured to make a notification for the degradation state SOH that is of the lithium metal secondary battery and is calculated by the degradation state calculator.

7. A degradation suppression system, comprising:
the degradation state estimation device according to claim 2; and
a degradation suppression controller configured to, based on the degradation state SOH calculated by the degradation state calculator, execute degradation suppression control to suppress degradation of the lithium metal secondary battery.

8. The degradation suppression system according to claim 7, wherein the degradation suppression controller executes the degradation suppression control in a case where a value of ‘second resistance value’/‘first resistance value’ that is a ratio of the second resistance value with respect to the first resistance value has exceeded 3.

9. A degradation state estimation method for estimating a degradation state of a lithium metal secondary battery that includes lithium metal in a negative electrode, the degradation state estimation method comprising:
a resistance value history acquisition step of acquiring a history for a resistance value of the lithium metal secondary battery in discharging for a predetermined amount of time; and
a degradation state calculation step of, in a case where a state of charge SOC of the lithium metal secondary battery has entered a predetermined range, calculating a degradation state SOH of the lithium metal secondary battery, based on the history for the resistance value acquired in the resistance value history acquisition step.

10. The degradation state estimation method according to claim 9, wherein
in the resistance value history acquisition step, a history for a first resistance value that is of the lithium metal secondary battery in discharging for a first amount of time and a history for a second resistance value that is of the lithium metal secondary battery in discharging for a second amount of time that is longer than the first amount of time are acquired, and
in the degradation state calculation step, the degradation state SOH of the lithium metal secondary battery is calculated based on the history for the first resistance value and the history for the second resistance value that are acquired in the resistance value history acquisition step.

11. The degradation state estimation method according to claim 10, wherein
in the resistance value history acquisition step, the history for the first resistance value and the history for the second resistance value are acquired while a vehicle is traveling, and
in the degradation state calculation step, the degradation state SOH is calculated in a case where the state of charge SOC of the lithium metal secondary battery has become less than or equal to 30%.

12. The degradation state estimation method according to claim 10, wherein the first amount of time is 1 second, and the second amount of time is 30 seconds.

13. The degradation state estimation method according to claim 9, further comprising:
a charge/discharge control step of, in a case where the state of charge SOC of the lithium metal secondary battery is within the range of 50% to 90%, executing charge/discharge control to pause a current during charging of the lithium metal secondary battery, discharge the lithium metal secondary battery for a predetermined amount of time, and resume charging of the lithium metal secondary battery,
wherein in the resistance value history acquisition step, the history for the resistance value is acquired while charging the lithium metal secondary battery, and
in the degradation state calculation step, the degradation state SOH is calculated based on the history for the resistance value that is acquired in the resistance value history acquisition step while the lithium metal secondary battery is charging.

14. A degradation suppression method, comprising:
the resistance value history acquisition step and the degradation state calculation step in the degradation state estimation method according to claim 10; and
a degradation suppression control step of, based on the degradation state SOH calculated in the degradation state calculation step, executing degradation suppression control to suppress degradation of the lithium metal secondary battery.

15. The degradation suppression method according to claim 14, wherein in the degradation suppression control step, the degradation suppression control is executed in a case where a value of ‘second resistance value’/‘first resistance value’ that is a ratio of the second resistance value with respect to the first resistance value has exceeded 3.
